(19) United States
(12) Patent Application Publication
(10) Pub. No.: US 2015/0076654 A1
(43) Pub. Date: Mar. 19, 2015

(54) ENLARGED FIN TIP PROFILE FOR FINS OF A FIELD EFFECT TRANSISTOR (FINFET) DEVICE

(71) Applicant: GLOBAL FOUNDRIES Inc., Grand Cayman (KY)

(72) Inventors: Michael Ganz, Clifton Park, NY (US); Eric S. Kozarsky, Ballston Spa, NY (US)

(73) Assignee: GLOBAL FOUNDRIES Inc., Grand Cayman (KY)

(21) Appl. No.: 14/028,728

(22) Filed: Sep. 17, 2013

(51) Int. Cl. H01L 29/06; H01L 21/76

(52) U.S. Cl. CPC H01L 29/0642; H01L 21/76
USPC 257/506; 438/404

(57) ABSTRACT

Approaches for providing enlarged fin tips for a set of fins of a fin field effect transistor device (FinFET) are disclosed. Specifically, approaches are provided for patterning a hardmask formed over a substrate; forming a set of fin tips from the substrate using a first etch; and forming a set of fins from the substrate using a second etch, wherein each of the set of fin tips has a width greater than a most narrow section of each of the set of fins. Each of the fin tips has a tapered profile that enlarges towards a top end thereof to compensate for erosion losses during processing.

### BACKGROUND

1. Technical Field

This invention relates generally to the field of semiconductors, and more particularly, to forming fin tips for a set of fins of a finFET device.

2. Related Art

A typical integrated circuit (IC) chip includes a stack of several levels or sequentially formed layers of shapes. Each layer is stacked or overlaid on a prior layer and patterned to form the shapes that define devices (e.g., field effect transistors (FETs)) and connect the devices into circuits. In a typical state of the art complementary insulated gate FET process, such as what is normally referred to as CMOS, layers are formed on a wafer to form the devices on a surface of the wafer. Further, the surface may be the surface of a silicon layer on a silicon on insulator (SOI) wafer. A simple FET is formed by the intersection of two shapes, a gate layer rectangle on a silicon island formed from the silicon surface layer. Each of these layers of shapes, also known as mask levels or layers, may be created or printed optically through well known photolithographic masking, developing and level definition, e.g., etching, implanting, deposition, etc.

The FinFET is a transistor design that attempts to overcome the issues of short-channel effect encountered by deep submicron transistors, such as drain-induced barrier lowering (DIBL). Such effects make it harder for the voltage on a gate electrode to deplete the channel underneath and stop the flow of carriers through the channel—in other words, to turn the transistor off. By raising the channel above the surface of the wafer instead of creating the channel just below the surface, it is possible to wrap the gate around all but one of its sides, providing much greater electrostatic control over the carriers within it.

In FinFET processing, fin erosion occurs during the dummy gate etch and post gate block implants. This erosion reduces the fin height and width, which may degrade device performance, e.g., by increasing resistance. Fin erosion also makes it difficult to control the final fin profile. Furthermore, fin erosion is problematic because the fins in finFET technology are the channels. If the channels are damaged, all electrical parameters are negatively affected. Currently, fin erosion is difficult to prevent as many clean and etch steps erode the exposed fins. This is even more severe when the fins are amorphized by the implants. It is difficult to protect the fins without limiting the overall process or causing even more damage.

As shown in the prior art device 10 of FIG. 1(a), a plurality of fins 12 are formed partially embedded in a shallow trench isolation (STI) layer 14 on a semiconductor substrate 16. However, following clean and etch processing steps, the tips of fins 12 extending above STI layer 14 become eroded, as shown in FIG. 1(b). The initial rectangular shape 18 of each fin 12 takes on a more narrow, pointed profile following processing. This reduced fin tip height and width causes device performance degradation.

### SUMMARY

In general, approaches for providing enlarged fin tips for a set of fins of a fin field effect transistor device (FinFET) are disclosed. Specifically, approaches are provided for patterning a hardmask formed over a substrate; forming a set of fin tips from the substrate using a first etch; and forming a set of fins from the substrate using a second etch, wherein each of the set of fin tips has a width greater than a most narrow section of each of the set of fins. Each of the fin tips has a tapered profile that enlarges towards a top end thereof to compensate for erosion losses during processing.

One aspect of the present invention includes a method for forming a fin field effect transistor (FinFET) device, the method comprising: patterning a hardmask formed over a substrate; forming a set of fin tips from the substrate using a first etch; and forming a set of fins from the substrate using a second etch, wherein each of the set of fin tips has a width greater than a most narrow section of each of the set of fins.

Another aspect of the present invention includes a method for forming a set of fins each having enlarged fin tips in a fin field effect transistor (FinFET) device, the method comprising: patterning a hardmask formed over a substrate; forming a set of fin tips from the substrate using a first etch; and forming a set of fins from the substrate using a second etch, wherein each of the set of fin tips has a width greater than a most narrow section of each of the set of fins.

Yet another aspect of the present invention includes a fin-shaped field effect transistor (FinFET) device, comprising: a substrate; and a set of fins formed from the substrate, each of the set of fins comprising an enlarged fin tip having a width greater than a most narrow section of each of the set of fins.

### BRIEF DESCRIPTION OF THE DRAWINGS

These and other features of this invention will be more readily understood from the following detailed description of the various aspects of the invention taken in conjunction with the accompanying drawings in which:

FIG. 1(a) shows a cross-sectional view of a prior art FinFET semiconductor device;

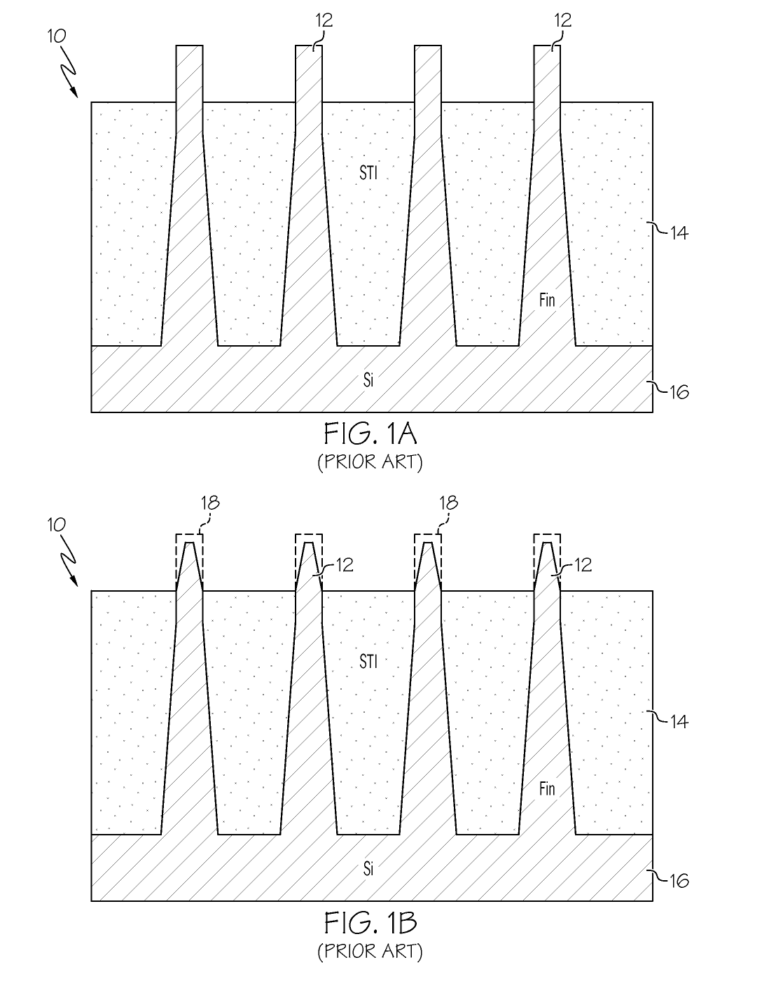

FIG. 1(b) shows a cross-sectional view of the prior art FinFET semiconductor device of FIG. 1(a) following device processing;

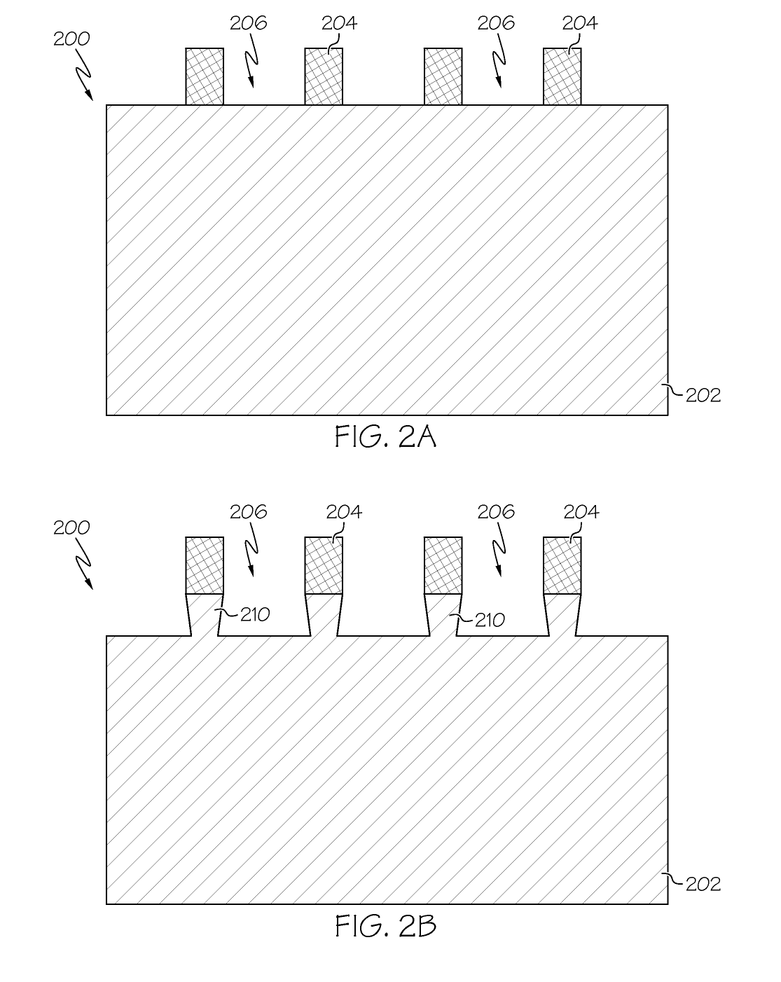

FIGS. 2(a)-(e) show cross-sectional views of an approach for forming enlarged fin tips for a set of fins of a FinFET semiconductor device according to illustrative embodiments;

FIG. 3 shows a cross-sectional view of a variety of fin tip profiles according to illustrative embodiments; and

FIG. 4 shows a process flow for forming enlarged fin tips for a set of fins of a FinFET device according to illustrative embodiments.

The drawings are not necessarily to scale. The drawings are merely representations, not intended to portray specific parameters of the invention. The drawings are intended to depict only typical embodiments of the invention, and therefore should not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines, which would otherwise be visible in a “true” cross-sectional view, for illustrative clarity. Furthermore, for clarity, some reference numbers may be omitted in certain drawings.

### DETAILED DESCRIPTION

Exemplary embodiments will now be described more fully herein with reference to the accompanying drawings, in which exemplary embodiments are shown. It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art.

As mentioned above, disclosed herein are approaches for providing enlarged fin tips for a set of fins of a FinFET device. Specifically, approaches are provided for patterning a hardmask formed over a substrate; forming a set of fin tips from the substrate using a first etch; and forming a set of fins from the substrate using a second etch, wherein each of the set of fin tips has a width greater than a most narrow section of each of the set of fins. Each of the fin tips has a tapered profile that enlarges towards a top end thereof to compensate for erosion losses during processing. This eliminates the need for complex and expensive process changes implemented to reduce the inherent fin erosion.

The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure, e.g., a first layer, is present on a second element, such as a second structure, e.g. a second layer, wherein intervening elements, such as an interface structure, e.g. interface layer, may be present between the first element and the second element.

As used herein, “depositing” may include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

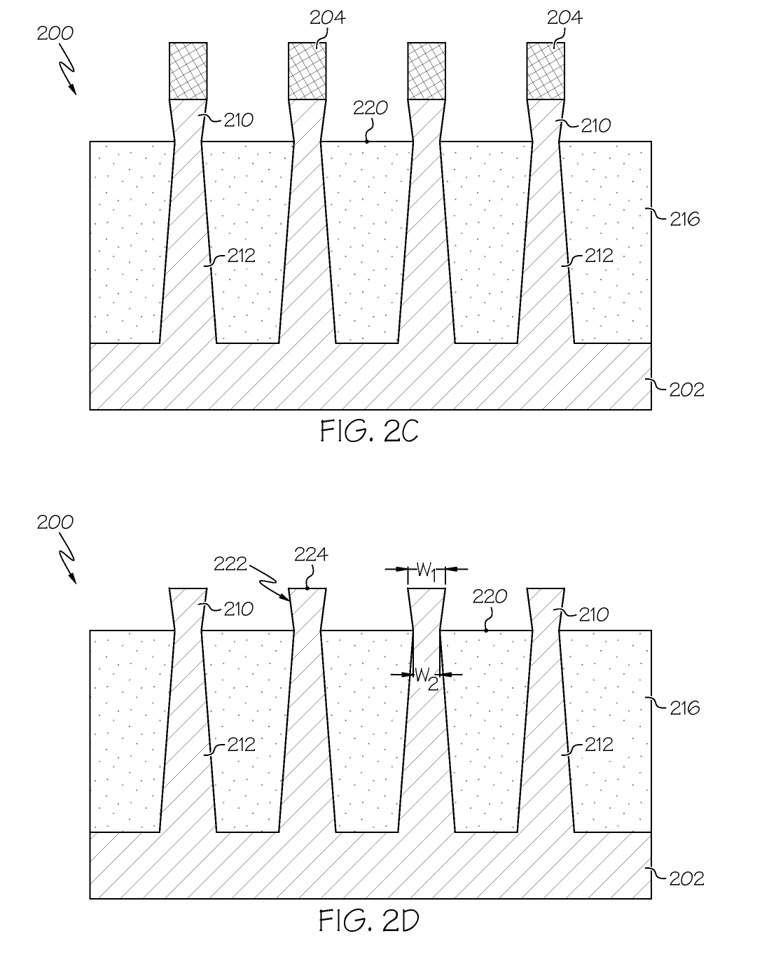

With reference again to the figures, FIGS. 2(a)-(e) demonstrate an approach for forming enlarged fin tips for a set of fins of a FinFET device to compensate for damage during subsequent processing according to an illustrative embodiment of the invention. As shown in the cross-sectional view of FIG. 2(a), device 200 comprises a substrate 202, and a hardmask 204 formed over substrate 202. The term “substrate” as used herein is intended to include a semiconductor substrate, a semiconductor epitaxial layer deposited or otherwise formed on a semiconductor substrate and/or any other type of semiconductor body, and all such structures are contemplated as falling within the scope of the present invention. For example, the semiconductor substrate may comprise a semiconductor wafer (e.g., silicon, SiGe, or an SOI wafer) or one or more die on a wafer, and any epitaxial layers or other type semiconductor layers formed thereover or associated therewith. A portion or the entire semiconductor substrate may be amorphous, polycrystalline, or single-crystalline. In addition to the aforementioned types of semiconductor substrates, the semiconductor substrate employed in the present invention may also comprise a hybrid oriented (HOT) semiconductor substrate in which the HOT substrate has surface regions of different crystallographic orientation. The semiconductor substrate may be doped, undoped or contain doped regions and undoped regions therein. The semiconductor substrate may contain regions with strain and regions without strain therein, or contain regions of tensile strain and compressive strain.

In one embodiment, hardmask 204 may comprise silicon nitride (SiN), silicon dioxide (SiO2), or any other material(s) suitable as a hardmask, including silicon oxynitride (SiON), silicon oxycarbide (SiOC), and the like. Hardmask 204 can be prepared by PVD, CVD, spin coating, etc., depending on the material. In a preferred embodiment, hardmask 204 is formed using a sidewall image transfer (SIT) technique. In this approach, a conformal SIT spacer is formed over a patterned sacrificial mandrel, the spacer is etched back to expose the top surfaces of the mandrel, and the mandrel is removed, leaving the portion of the SIT spacer that was located on the sides of the mandrel. This SIT spacer material can then be used as hardmask 204 or used to pattern any additional hard mask layers. It will be appreciated that hardmask 204 may comprise multiple stacked layers, and is not limited to the uniform layer shown.

Next, a fin etch process is performed, whereby openings 206 are extended into substrate 202 to form a set of fin tips 210, as shown in FIG. 2(b). In one embodiment, substrate 202 is etched using an isotropic dry etch (e.g., using CF₄/O₂ with no bias, and moderate pressure) to form tapered fin tips 210. Hardmask 204 remains atop each fin tip 210 to protect the silicon during the etch process.

A set of fins 212 is then formed from substrate 202, as shown in FIG. 2(c). In this step, substrate 202 is etched using a highly anisotropic dry etch (e.g., SF₆/CH₂F₂/O₂/Ar, modulating bias, pressure, and power, etc.). As shown, a shallow trench isolation (STI) layer 216 is provided over substrate 202 and between each of set of fins 212. Each fin tip 210 extends above a top surface 220 of STI layer 216.

Next, hardmask 204 is removed, as shown in FIG. 2(d), revealing the initial enlarged fin tips 210. In this embodiment, each fin tip 210 has a tapered sidewall profile 222 that enlarges (i.e., flares/angles outward) towards a top end 224 thereof. As such, each fin tip 210 has a width W1 that is greater than a most narrow section W2 of each of set of fins 212. The most narrow section W2 generally coincides with a planar, horizontal location of top surface 220 of STI layer 216.

Enlarged fin tips 210 compensate for the negative impact of fin erosion during subsequent processing. For example, subsequent processing (not shown) may include forming a set of gate stacks over fins 212, and forming source and drain regions across the gate stack. Source and drain regions may be formed by ion-implanting a source/drain region or by removing a portion of the fin and epitaxially re-growing the removed portion under doping conditions to form a source/drain region.

The gate structures may be fabricated using any suitable process including one or more photolithography and etch processes. The photolithography process may include forming a photoresist layer (not shown) overlying substrate 202 (e.g., on a silicon layer), exposing the resist to a pattern, performing post-exposure bake processes, and developing the resist to form a masking element including the resist. The masking element may then be used to etch each gate into the silicon layer, e.g., using reactive ion etch (RIE) and/or other suitable processes.

FIG. 2(e) represents FinFET device 200 following gate etching and post gate block implantation. As shown, fin tips 210 have been reduced in height and width, particularly at top end 224. However, because fin tips 210 were initially enlarged and tapered, e.g., as shown in FIG. 2(d), a more rectangular exposed fin remains following processing. This, in turn, decreases the resistance caused by unwanted fin erosion.

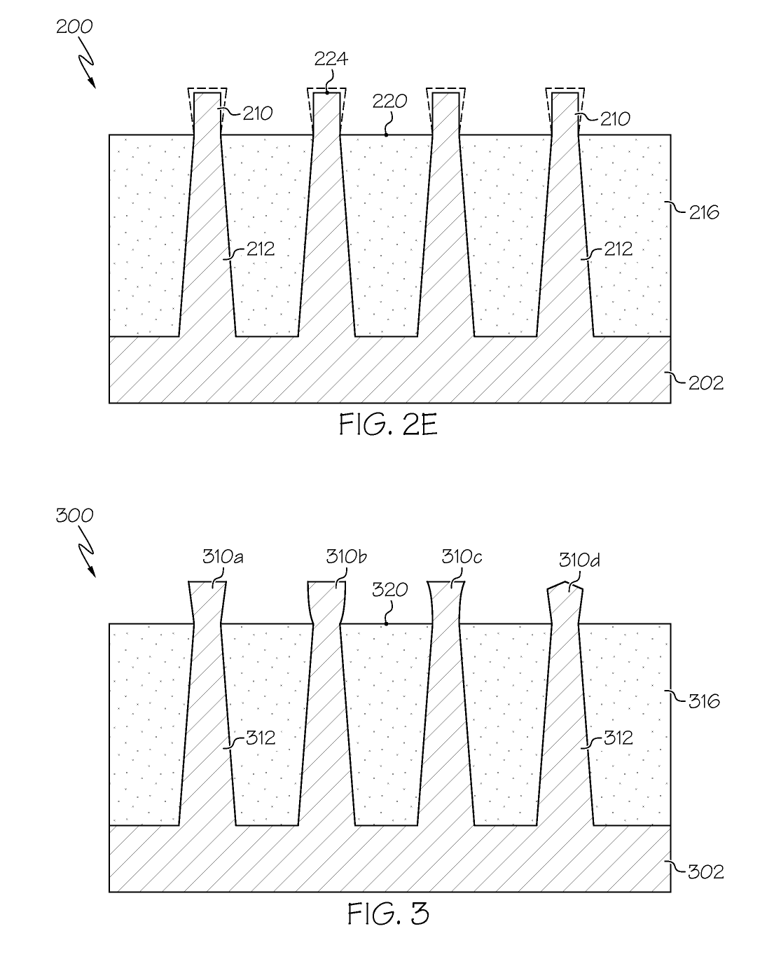

It will be appreciated that the invention is not limited to any particular fin tip profile/shape. For example, as shown in FIG. 3, FinFET device 300 comprises fins 312 with fin tips 310(a)-(d) having sidewall profiles comprising one of: flat, tapered (e.g., FIG. 3(a)), rounded out (e.g., FIG. 3(b)), rounded in (e.g., FIG. 3(c)), and inverted conical (e.g., FIG. 3(d)). Various initial fin tip shapes can be utilized based on the particular fin erosion experienced.

In various embodiments, design tools can be provided and configured to create the datasets used to pattern the semiconductor layers as described herein. For example data sets can be created to generate photomasks used during lithography operations to pattern the layers for structures as described herein, including a substrate, and a set of fins formed from the substrate, each of the set of fins comprising an enlarged fin tip having a width greater than a most narrow section of each of the set of fins. Such design tools can include a collection of one or more modules and can also be comprised of hardware, software or a combination thereof. Thus, for example, a tool can be a collection of one or more software modules, hardware modules, software/hardware modules or any combination or permutation thereof.

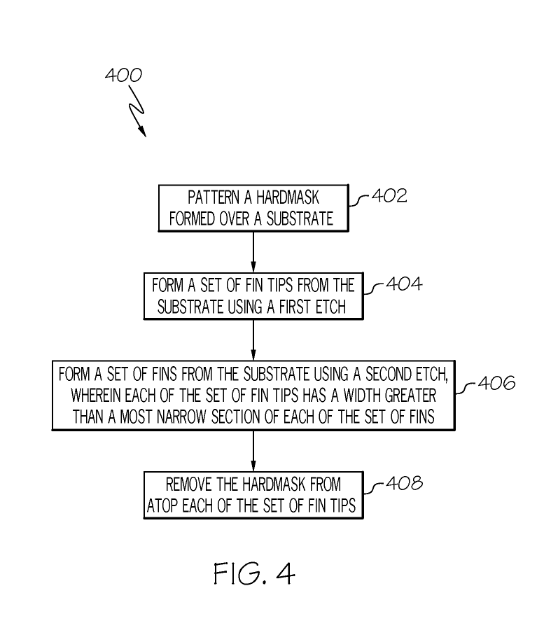

The software/hardware modules of the tool may be configured to perform a process 400, as shown in FIG. 4. Process 400 includes: patterning a hardmask formed over a substrate (402); forming a set of fin tips from the substrate using a first etch (404); forming a set of fins from the substrate using a second etch, wherein each of the set of fin tips has a width greater than a most narrow section of each of the set of fins (406); and removing the hardmask from atop each of the set of fin tips (408).

As another example, the tool can be a computing device or other appliance on which software runs or in which hardware is implemented. As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

It is apparent that there has been provided methods for forming a set of fins each having enlarged fin tips in a FinFET device. While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

1. A method for forming a fin field effect transistor (FinFET) device, the method comprising:
patterning a hardmask formed over a substrate;
forming a set of fin tips from the substrate using a first etch; and
forming a set of fins from the substrate using a second etch, wherein each of the set of fin tips has a width greater than a most narrow section of each of the set of fins.

2. The method according to claim 1, further comprising removing the hardmask from atop each of the set of fin tips.

3. The method according to claim 1, further comprising providing a shallow trench isolation layer between each of the set of fins.

4. The method according to claim 1, the patterning the hardmask comprising forming a set of openings in the hardmask.

5. The method according to claim 4, the forming the set of fin tips comprising etching the substrate within each of the set of openings in the hardmask.

6. The method according to claim 1, wherein the first etch comprises an isotropic dry etch, and wherein the second etch comprises an anisotropic dry etch.

7. The method according to claim 1, each of the set of fin tips having a tapered profile that enlarges towards a top end.

8. A method for forming a set of fins each having enlarged fin tips in a fin field effect transistor (FinFET) device, the method comprising:
patterning a hardmask formed over a substrate;
forming a set of fin tips from the substrate using a first etch; and
forming a set of fins from the substrate using a second etch, wherein each of the set of fin tips has a width greater than a most narrow section of each of the set of fins.

9. The method according to claim 8, further comprising removing the hardmask from atop each of the set of fin tips.

10. The method according to claim 8, further comprising providing a shallow trench isolation layer between each of the set of fins.

11. The method according to claim 8, the patterning the hardmask comprising forming a set of openings in the hardmask.

12. The method according to claim 11, the forming the set of fin tips comprising etching the substrate within each of the set of openings in the hardmask.

13. The method according to claim 8, wherein the first etch comprises an isotropic dry etch, and wherein the second etch comprises an anisotropic dry etch.

14. The method according to claim 1, each of the set of fin tips having a tapered profile that enlarges towards a top end.

15. A fin-shaped field effect transistor (FinFET) device, comprising:
a substrate; and
a set of fins formed from the substrate, each of the set of fins comprising an enlarged fin tip having a width greater than a most narrow section of each of the set of fins.

16. The FinFET device according to claim 15, each of the set of fin tips having a tapered sidewall profile that enlarges towards a top end.

17. The FinFET device according to claim 16, the tapered sidewall profile comprising one of: rounded out, and rounded in.

18. The FinFET device according to claim 16, wherein the top end has an inverted conical shape.

19. The FinFET device according to claim 15, further comprising a shallow trench isolation (STI) layer between each of the set of fins.

20. The FinFET device according to claim 19, each of the set of fin tips extending above a top surface of the STI layer.
